(19) United States
(12) Patent Application Publication
(10) Pub. No.: US 2025/0127025 A1
(43) Pub. Date: Apr. 17, 2025

(54) DISPLAY DEVICE AND METHOD OF MANUFACTURING THE SAME

(71) Applicant: Samsung Display Co., Ltd., Yongin-si (KR)

(72) Inventors: Jaeyoung Jang, Yongin-si (KR); Youngwoon Kim, Yongin-si (KR); Chanhee Park, Yongin-si (KR); Chulwoo Hyun, Yongin-si (KR)

(73) Assignee: Samsung Display Co., Ltd., Yongin-si (KR)

(21) Appl. No.: 18/911,974

(22) Filed: Oct. 10, 2024

(30) Foreign Application Priority Data
Oct. 11, 2023 (KR) 10-2023-0135399

(51) Int. Cl. H10K 59/80; H10K 59/12

(52) U.S. Cl. CPC H10K 59/8794; H10K 59/1201; H10K 59/873

(57) ABSTRACT

A display device includes a display panel, a cover panel disposed under the display panel and including a heat dissipation layer, a first release film disposed under the cover panel and having a step difference with an edge of the cover panel, and a second release film disposed under the first release film and having a step difference with an edge of the first release film.

### CROSS-REFERENCE TO RELATED APPLICATION(S)

This application claims priority to and benefits Korean Patent Application No. 10-2023-0135399 under 35 U.S.C. § 119, filed on Oct. 11, 2023, in the Korean Intellectual Property Office (KIPO), the entire contents of which are incorporated herein by reference.

### BACKGROUND

### 1. Technical Field

The disclosure relates to a display device and a method of manufacturing the same.

### 2. Description of the Related Art

A display device visually displays data. A display device may provide an image by using light emitting diodes. The usage of display devices has been diversified, and various designs have been attempted to improve the quality of display devices.

### SUMMARY

Embodiments include a display device and a method of manufacturing the same.

Additional aspects will be set forth in part in the description which follows and, in part, will be apparent from the description, or may be learned by practice of the embodiments of the disclosure.

According to an embodiment, a display device may include a display panel, a cover panel disposed under the display panel and including a heat dissipation layer, a first release film disposed under the cover panel and having a step difference with an edge of the cover panel, and a second release film disposed under the first release film and having a step difference with an edge of the first release film.

According to an embodiment, a thickness of the first release film may be in a range of about 10 μm to about 20 μm in a thickness direction of the display panel.

According to an embodiment, at least a portion of the cover panel may be exposed due to the step difference with the edge of the first release film.

According to an embodiment, a step difference may be formed between the first release film and an edge of the heat dissipation layer of the cover panel.

According to an embodiment, the heat dissipation layer may include copper (Cu).

According to an embodiment, the cover panel may further include a cushion layer disposed on the heat dissipation layer.

According to an embodiment, a step difference may be formed between the cover panel and an edge of the display panel.

According to an embodiment, the display device may further include a cover glass disposed on the display panel.

According to an embodiment, a step difference may be formed between the cover glass and an edge of the display panel.

According to an embodiment, at least a portion of the cover glass may be exposed due to the step difference with the edge of the display panel.

According to an embodiment, the display device may further include a coating layer disposed on a portion of the heat dissipation layer of the cover panel exposed by the first release film.

According to an embodiment, the coating layer may include at least one of propane (C₃H₈) and butane (C₄H₁₀).

According to an embodiment, the coating layer may be arranged in at least a portion of a side of the first release film.

According to an embodiment, a thickness of the coating layer may be less than or equal to about 20 μm in a thickness direction of the display panel.

According to an embodiment, the coating layer may be arranged at a side of the cover panel and at least a portion of a lower surface of and a side of the display panel.

According to an embodiment, a method of manufacturing a display device may include arranging a cover panel including a heat dissipation layer on a display panel, arranging a first release film on the cover panel such that a step difference with an edge of the cover panel may be formed, arranging a second release film on the first release film such that a step difference with an edge of the first release film may be formed, and forming a coating layer by applying a coating layer forming material on the heat dissipation layer of the cover panel about 0.1 mm apart from the edge of the first release film.

According to an embodiment, a thickness of the first release film may be in a range of about 10 μm to about 20 μm in a thickness direction of the display panel.

According to an embodiment, the coating layer may include at least one of propane (C₃H₈) and butane (C₄H₁₀).

According to an embodiment, the coating layer may be disposed on a portion of the heat dissipation layer of the cover panel.

According to an embodiment, the method may further include forming a cover glass under the display panel.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a rear side of a display device;

FIG. 2 is a schematic cross-sectional view of at least a portion of a side of the display device at which a coating layer is arranged;

FIGS. 3 to 7 are schematic cross-sectional views showing a method of manufacturing the display device;

FIG. 8 are photographs schematically showing a thickness of the coating layer applied on an upper portion of a heat dissipation layer;

FIG. 9 is a schematic diagram of an equivalent circuit of a pixel; and

FIG. 10 is a schematic cross-sectional view of the display device.

### DETAILED DESCRIPTION

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, wherein the same or corresponding elements are denoted by the same reference numerals throughout and a repeated description thereof is omitted.

In the specification, the terms “first” and “second” are not used in a limited sense and are used to distinguish one component from another component.

As used herein, the singular expressions “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Sizes of elements in the drawings may be exaggerated for convenience of explanation. For example, because sizes and thicknesses of elements in the drawings are arbitrarily illustrated for convenience of explanation, the disclosure is not limited thereto.

When a certain embodiment may be implemented differently, a specific process order may be performed differently from the described order. For example, two consecutively described processes may be performed substantially at the same time or performed in an order opposite to the described order.

In this specification, the expression “A and/or B” may indicate A, B, or A and B. Also, the expression “at least one of A and B” may indicate A, B, or A and B.

In the embodiments hereinafter, it will be understood that when an element, an area, or a layer is referred to as being connected to another element, area, or layer, it can be directly and/or indirectly connected to the other element, area, or layer. For example, it will be understood in this specification that when an element, an area, or a layer is referred to as being in contact with or being electrically connected to another element, area, or layer, it can be directly and/or indirectly in contact with or electrically connected to the other element, area, or layer.

The x-axis, the y-axis and the z-axis are not limited to three axes of the rectangular coordinate system and may be interpreted in a broader sense. For example, the x-axis, the y-axis, and the z-axis may be perpendicular to one another, or may represent different directions that are not perpendicular to one another.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

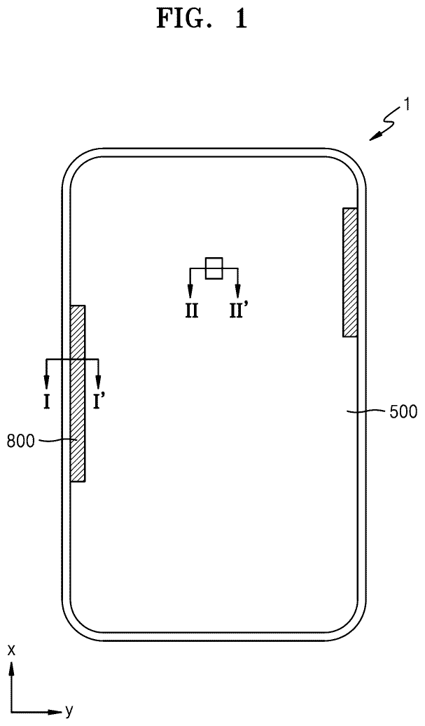

FIG. 1 is a schematic plan view of a rear side of a display device.

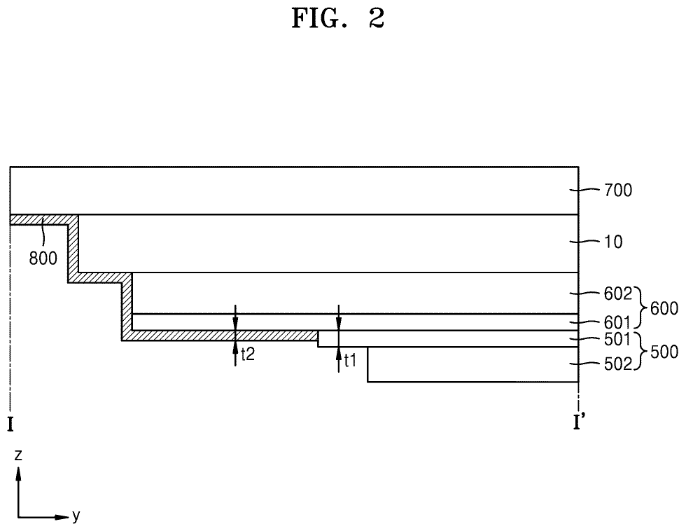

Referring to FIG. 1, a release film 500 may be disposed below a display panel 10 (FIG. 2). The release film 500 may not be arranged in at least a portion of a side of the display device 1. A coating layer 800 may be arranged in at least a portion of a side of the display device 1 in which the release film 500 is not disposed. The coating layer 800 may have anti-static characteristics.

A sound key or a power key may be arranged in at least a portion of the side of the display device 1. In case that a person hand-touches the sound key or power key, an anti-static effect may occur in at least a portion of the side of the display device 1, thereby causing a defect in the display device 1. In an embodiment, in case that the coating layer 800 having an anti-static characteristic in at least a portion of the display device 1 is provided, even without the touch of a human hand, the occurrence of anti-static may be prevented and the reliability and quality of the display device 1 may be improved.

FIG. 2 shows a schematic cross-sectional view of at least a portion of the side of the display device in which the coating layer is arranged. In particular, FIG. 2 is a schematic cross-sectional view of the side of the display device taken along line I-I′ of FIG. 1.

Referring to FIG. 2, a cover glass 700 may be disposed on (e.g., a z direction) the display panel 10. A cover panel 600 including a heat dissipation layer 601 may be disposed under the display panel 10. The heat dissipation layer 601 may include copper Cu. The cover panel 600 and an edge of the display panel 10 may have a step difference. At least a portion of a lower surface of the cover glass 700 may be exposed due to the step difference with the edge of the display panel 10.

The cover panel 600 may include a cushion layer 602 disposed on (e.g., the z direction) the heat dissipation layer 601. The cover panel 600 including the cushion layer 602 and the heat dissipation layer 601 may be arranged under the display panel 10 (e.g. a-z direction) to protect the display panel 10 from pressure outside the display device 1 (FIG. 1) and prevent the temperature of the rear side of the display device 1 from rising due to heat generated in the display device 1, thereby improving the quality and reliability of the display device 1.

The release film 500 may be disposed under (e.g., the −z direction) the cover panel 600. The release film 500 may include a first release film 501 and a second release film 502. The first release film 501 may be in contact with a lower surface of the heat dissipation layer 601 of the cover panel 600. The first release film 501 and an edge of the cover panel 600 may have a step difference. For example, the first release film 501 may form a step difference with an edge of the heat dissipation layer 601 of the cover panel 600. Due to the step difference between the cover panel 600 and the edge of the first release film 501, at least a portion of the lower surface of the cover panel 600 may be exposed. For example, due to the step difference between the edge of the cover panel 600 and the first release film 501, at least a portion of the lower surface of heat dissipation layer 601 of the cover panel 600 may be exposed.

The second release film 502 may be disposed under (e.g., the −z direction) the first release film 501. The first release film 501 and an edge of the second release film 502 may have a step difference. In other words, at least a portion of the lower surface of the first release film 501 may be exposed due to the step difference with the edge of the second release film 502.

In an embodiment, a thickness t1 of the first release film 501 may be in a range of about 10 μm to about 20 μm. In case that the thickness t1 of the first release film 501 is less than about 10 μm, it may not readily manufacture the release film, thereby causing a defect. Since a relatively less step difference between the first release film 501 and an upper surface the heat dissipation layer 601 of the cover panel 600, during a process of applying a coating layer forming material on the heat dissipation layer 601, the coating layer forming material may be pushed over the first release film 501 to form the coating layer 800 on an unnecessary portion, for example, on the first release film 501. In case that the thickness t1 of the first release film 501 is greater than 20 μm, the coating layer forming material 800 may be clumped together at the side of the first release film 501, and thus, a thickness t2 of the coating layer 800 may be greater than 20 μm. In case that the thickness t2 of the coating layer 800 is greater than 20 μm, pressure may not be appropriately applied to the display device 1 (FIG. 1) when attaching the set on the display device 1 (FIG. 1), thereby decreasing the connecting force between the set and the display device 1. However, the disclosure is not limited thereto.

The coating layer 800 may be disposed on the heat dissipation layer 601 of the cover panel 600 exposed due to the step difference with the edge of the first release film 501. The coating layer 800 may have anti-static characteristics. The coating layer 800 may include at least one of propane (C₃H₈) and butane (C₄H₁₀). The coating layer 800 may be disposed on at least a portion of the side of the first release film 501. The coating layer 800 may be also disposed on at least a portion of the side of the cover panel 600, at least a portion of the lower surface of the display panel 10 and the side of the display panel 10, and at least a portion of the lower surface of the cover glass 700.

The thickness t2 of the coating layer 800 may be less than or equal to about 20 μm. In case that the thickness t2 of the coating layer 800 is greater than 20 μm, pressure may not be appropriately applied to the display device 1 (FIG. 1) when attaching the set on the display device 1 (FIG. 1), thereby decreasing the connecting force between the set and the display device 1.

In case that the release film of the display device includes a single release film, the thickness of the single release film may be about 85 μm. In case that the coating layer forming material is applied on the heat dissipation layer 601, the coating layer forming material may be clumped at a side of a single release film, and thus, the thickness of the coating layer may be greater than 20 μm.

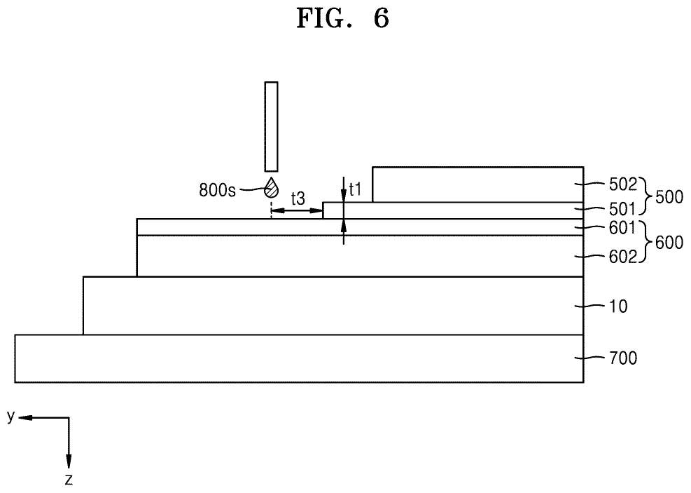

In an embodiment, the first release film 501 and the edge of the second release film 502 may have a step difference, and the thickness t1 of the first release film 501 may be in a range of about 10 μm to about 20 μm. In case that the thickness t1 of the first release film 501 is in a range of about 10 μm to about 20 μm, when forming the coating layer 800 by applying the coating layer forming material 800s (FIG. 6) on the heat dissipation layer 601, the thickness t2 of the coating layer 800 may be less than or equal to about 20 μm even in case that the coating layer forming material 800s is clumped at the side of the first release film 501 or is pushed over the first release film 501.

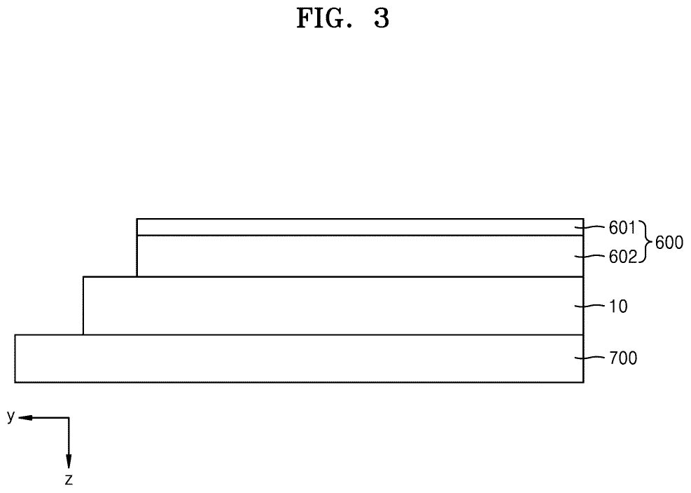

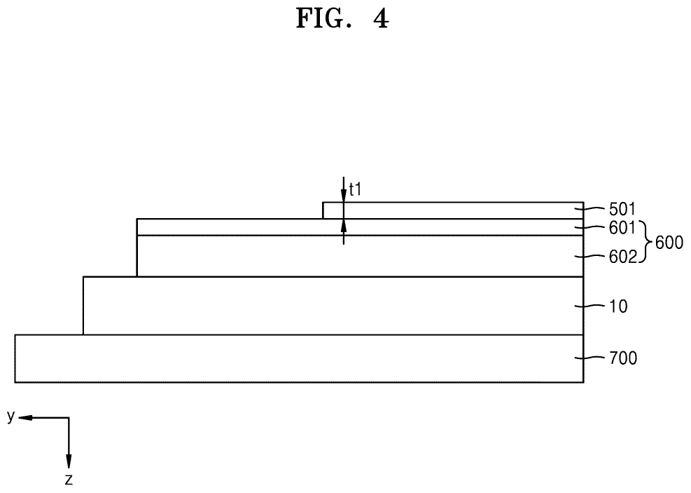

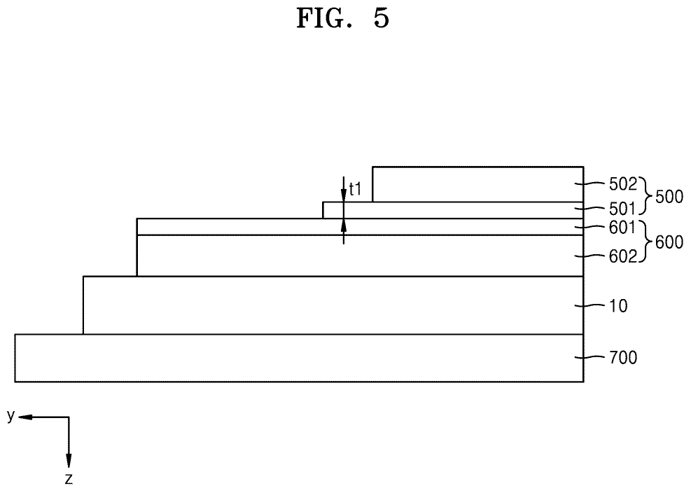

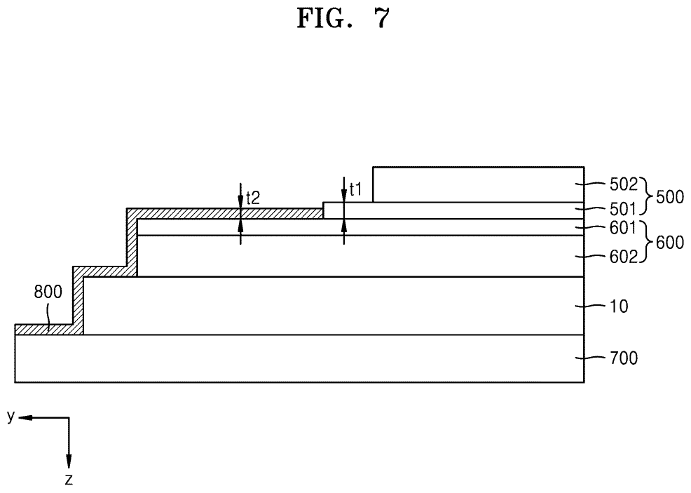

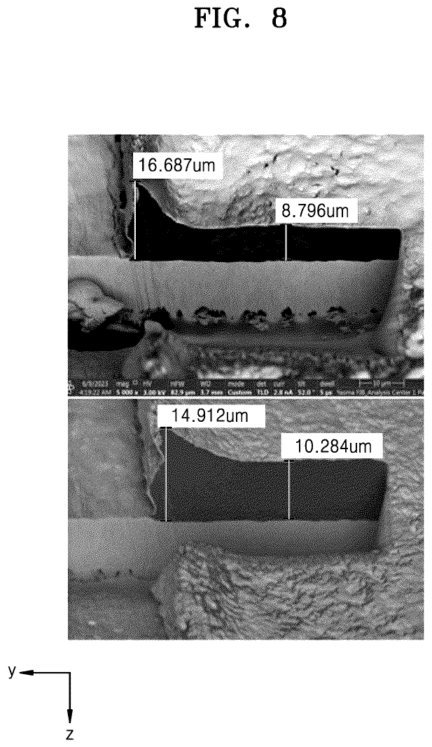

FIGS. 3 to 7 are schematic cross-sectional views showing a method of manufacturing the display device 1. FIG. 8 are photographs schematically showing the thickness of the coating layer 800 applied on the upper portion of the heat dissipation layer 601. FIGS. 3 to 7 are schematic cross-sectional views illustrating method of manufacturing the display device 1, and the lamination structure of the display device 1, and the direction of the upper portion and the lower portion may be different from those of the display device 1 of FIG. 2.

Referring to FIGS. 3 to 7, the cover panel 600 including the heat dissipation layer 601 may be disposed on the display panel 10. The cover panel 600 may include the heat dissipation layer 601 and the cushion layer 602. The cover glass 700 may be disposed under (e.g., the z direction) the display panel 10. The first release film 501 may be disposed on the cover panel 600 to have a step difference with the cover panel 600. For example, the first release film 501 may be disposed on the heat dissipation layer 601 of the cover panel 600 to have a step difference with the heat dissipation layer 601 of the cover panel 600.

The second release film 502 may be disposed on the first release film 501 to have a step difference with the edge of the first release film 501. At least a portion of the upper surface of the first release film 501 may be exposed due to the step difference with the second release film 502.

A coating layer 800 may be formed by applying a coating layer forming material 800s from an applier on the heat dissipation layer 601 of the cover panel 600 which is about 0.1 mm apart from an edge of the first release film 501. A shortest distance t3 between the edge of the first release film 501 and the applier may be about 0.1 mm. The coating layer forming material 800s may be coated on a location apart from the edge of the first release film 501 by about 0.1 mm, and thus, the coated coating layer forming material 800s may be prevented from being pushed over the first release film 501 and the upper portion of the first release film 501 being coated.

A thickness t1 of the first release film 501 may be in a range of about 10 μm to about 20 μm. In case that the thickness t1 of the first release film 501 is less than about 10 μm, it may not readily manufacture the release film, thereby causing a defect. Since a relatively less step difference occurs between the first release film 501 and the upper surface of the heat dissipation layer 601 of the cover panel 600, during a process of applying a coating layer forming material on the heat dissipation layer 601, the coating layer forming material 800s may be pushed over the first release film 501 to form the coating layer 800 on an unnecessary portion, for example, on the first release film 501. In case that the thickness t1 of the first release film 501 is greater than 20 μm, the coating layer forming material 800s may be clumped together at the side of the first release film 501, and thus, a thickness t2 of the coating layer 800 may be greater than 20 μm. In case that the thickness t2 of the coating layer 800 is greater than 20 μm, pressure may not be appropriately applied to the display device 1 (FIG. 1) when attaching the set on the display device 1 (FIG. 1), thereby decreasing the connecting force between the set and the display device 1. However, the disclosure is not limited thereto.

Referring to FIG. 8, even in case that a portion of the applied coating layer forming material 800s is clumped at the side of the first release film 501, the thickness t2 of the coating layer 800 at the side of the first release film 501 may be about 14 μm or about 16 μm. For example, the thickness t2 of the coating layer 800 at the side of the first release film 501 may be less than or equal to about 20 μm.

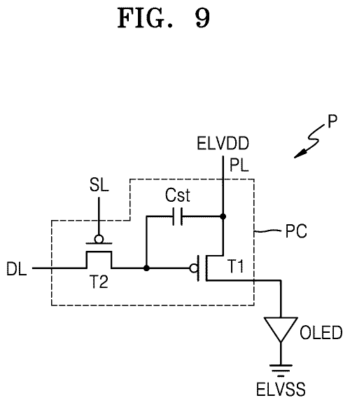

FIG. 9 is a schematic diagram of an equivalent circuit of a pixel.

Referring to FIG. 9, the pixel circuit PC may include an organic light-emitting diode OLED as a display element connected to the pixel circuit PC, as described in FIG. 2. The pixel circuit PC may include a first thin-film transistor T1, a second thin-film transistor T2, and a storage capacitor Cst. Each pixel P may emit light, such as red, green, or blue light, or emit red, green, blue, or white light, through the organic light-emitting diode OLED.

The second thin-film transistor T2 may be a switching thin-film transistor, may be connected to a scan line SL and a data line DL, and may be configured to transmit, to the first thin-film transistor T1, a data voltage provided from the data line DL, based on a switching voltage provided from the scan line SL. The storage capacitor Cst may be connected to the second thin-film transistor T2 and a driving voltage line PL and may be configured to store a voltage corresponding to a difference between a voltage received from the second thin-film transistor T2 and a first power voltage ELVDD supplied from the driving voltage line PL.

The first thin-film transistor T1 may be a driving thin-film transistor, may be connected to the driving voltage line PL and the storage capacitor Cst, and may be configured to control a driving current flowing from the driving voltage line PL to the organic light-emitting diode OLED, according to a value of the voltage stored in the storage capacitor Cst. The organic light-emitting diode OLED may emit light having a brightness according to the driving current. An opposite electrode (e.g., a cathode) of the organic light-emitting diode OLED may receive a second power voltage ELVSS.

FIG. 9 illustrates that the pixel circuit PC includes two thin-film transistors and one storage capacitor. However, the disclosure is not limited thereto. The number of thin-film transistors and the number of storage capacitors may be variously modified according to the design of the pixel circuit PC. For example, the pixel circuit PC may include two thin-film transistors, as described above, or four, five, or more thin-film transistors.

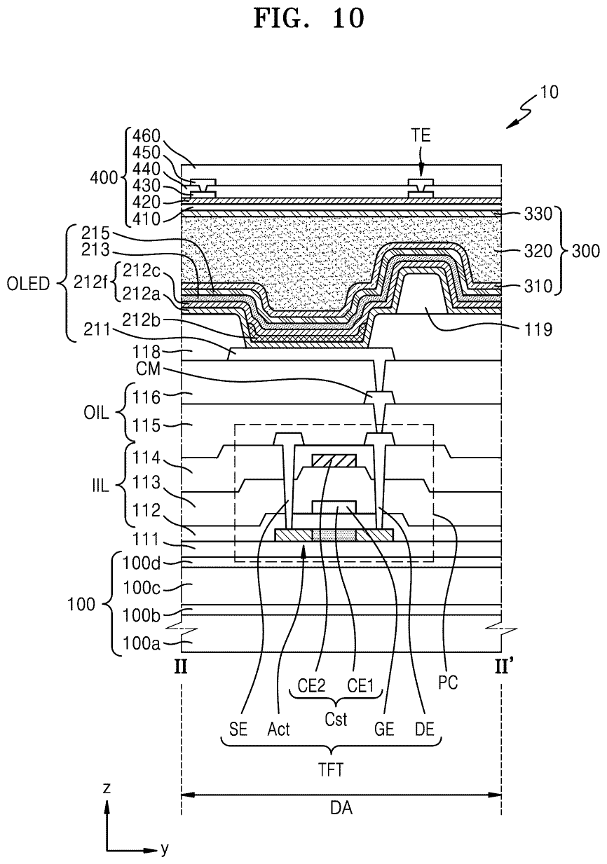

FIG. 10 is a schematic cross-sectional view of the display device 1. In particular, FIG. 10 is a schematic cross-sectional view of the display device 1 of FIG. 1 taken along line II-II′.

Referring to FIG. 10, the substrate 100 may include a first base layer 100a, a first barrier layer 100b, a second base layer 100c, and a second barrier layer 100d. In an embodiment, the first base layer 100a, the first barrier layer 100b, the second base layer 100c, and the second barrier layer 100d may be sequentially stacked in a thickness direction of the substrate 100.

At least one of the first base layer 100a and the second base layer 100c may include a polymer resin including polyethersulfone, polyarylate, polyetherimide, polyethylene naphthalate, polyethylene terephthalate, polyphenylene sulfide, polyimide, polycarbonate, cellulose triacetate, cellulose acetate propionate, or the like.

The first barrier layer 100b and the second barrier layer 100d, which are barrier layers that prevent the penetration of the external foreign materials, may include layers or a single layer including an inorganic material such as silicon nitride (SiNₓ), silicon oxide (SiO₂), and/or silicon oxynitride (SiON).

A buffer layer 111 may be disposed on the substrate 100. The buffer layer 111 may include an inorganic insulating material such as SiNₓ, SiON, and SiO₂ and may have a single-layer or multi-layer structure including the inorganic insulating material.

The inorganic insulating layer IIL may be disposed on the buffer layer 111. The inorganic insulating layer IIL may include a first gate insulating layer 112, a second gate insulating layer 113, and an interlayer insulating layer 114.

The pixel circuit PC may be arranged on the display area DA. The pixel circuit PC may include a thin-film transistor TFT and the storage capacitor Cst. The thin-film transistor TFT may include a semiconductor layer Act, a gate electrode GE, a source electrode SE, and a drain electrode DE.

The semiconductor layer Act may be disposed on the buffer layer 111. The semiconductor layer Act may include polysilicon. In another embodiment, the semiconductor layer Act may include amorphous silicon, an oxide semiconductor, or an organic semiconductor. The semiconductor layer Act may include a channel area, and a drain area and a source area respectively arranged on a side of the channel area.

The gate electrode GE may be disposed on the semiconductor layer Act. The gate electrode GE may overlap the channel area in a plan view. The gate electrode GE may include a low-resistance metal material. The gate electrode GE may include a conductive material including Mo, Al, Cu, Ti, etc. and may include layers or a single layer including the conductive material.

The first gate insulating layer 112 may be arranged between the semiconductor layer Act and the gate electrode GE. The first gate insulating layer 112 may include an inorganic insulating material such as SiO₂, SiNₓ, SiON, aluminum oxide (Al₂O₃), titanium oxide (TiO₂), tantalum oxide (Ta₂O₅), hafnium oxide (HfO₂), or zinc oxide (ZnO).

The second gate insulating layer 113 may be disposed on the gate electrode GE. The second gate insulating layer 115 may cover the gate electrode GE. The second gate insulating layer 113 may include an inorganic insulating material such as SiO₂, SiNₓ, SiON, Al₂O₃, TiO₂, Ta₂O₅, HfO₂, or ZnO.

A second capacitor plate CE2 of the storage capacitor Cst may be disposed on the second gate insulating layer 113. The second capacitor plate CE2 may overlap the gate electrode GE in a plan view. The gate electrode GE and the second capacitor plate CE2 overlapping each other with the second gate insulating layer 113 between the gate electrode GE and the second capacitor plate CE2 may form the storage capacitor Cst. For example, the gate electrode GE may function as a first capacitor plate CE1 of the storage capacitor Cst.

As described above, the storage capacitor Cst may overlap the thin-film transistor TFT in a plan view. However, the disclosure is not limited thereto. For example, the storage capacitor Cst may not overlap the thin-film transistor TFT in a plan view. For example, the first capacitor plate CE1 of the storage capacitor Cst may be a separate element from the gate electrode GE of the thin-film transistor TFT and may be spaced apart from the gate electrode GE of the thin-film transistor TFT in a plan view.

The second capacitor plate CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single-layer or multi-layer structure including the material described above.

The interlayer insulating layer 114 may be disposed on the second capacitor plate CE2. The interlayer insulating layer 114 may cover the second capacitor plate CE2. The interlayer insulating layer 114 may include an inorganic insulating material such as SiO₂, SiNₓ, SiON, Al₂O₃, TiO₂, Ta₂O₅, HfO₂, ZnO, or the like. The interlayer insulating layer 117 may have a single-layer or multi-layer structure including the inorganic insulating material.

The drain electrode DE and the source electrode SE may each be disposed on the interlayer insulating layer 114. The drain electrode DE and the source electrode SE may each be connected to the semiconductor layer Act through contact holes included in the first gate insulating layer 112, the second gate insulating layer 113, and the interlayer insulating layer 114. The drain electrode DE and the source electrode SE may include a material with high conductivity. The drain electrode DE and the source electrode SE may include a conductive material such as Mo, Al, Cu, Ti, etc. and may include layers or a single layer including the conductive material. For example, the drain electrode DE and the source electrode SE may have a multi-layer structure of Ti/Al/Ti.

The organic insulating interlayer OIL may be disposed on the inorganic insulating layer IIL. The organic insulating layer OIL may include a first organic insulating layer 115 and a second organic insulating layer 116. FIG. 6 illustrates that the display panel 10 includes two organic insulating layers OIL, but the disclosure is not limited thereto. In another embodiment, the display panel may include three or four organic insulating layers OIL.

The first organic insulating layer 115 may cover the drain electrode DE and the source electrode SE. The first organic insulating layer 115 may include an organic insulating material, such as a general-purpose polymer, such as polymethylmethacrylate (PMMA) or polystyrene (PS), polymer derivatives having a phenol-based group, an acryl-based polymer, an imide-based polymer, an arylether-based polymer, an amide-based polymer, a fluorine-based polymer, a p-xylene-based polymer, a vinyl alcohol-based polymer, and a blend thereof.

The connection electrode CM may be disposed on the first organic insulating layer 115, and the connection electrode CM may be connected to the drain electrode DE or the source electrode SE through a contact hole of the first organic insulating layer 115. The connection electrode CM may include a material with high conductivity. The connection electrode CM may include a conductive material such as Mo, Al, Cu, Ti, etc. and may include layers or a single layer including the conductive material. For example, the connection electrode CM may have a multi-layer structure of Ti/Al/Ti.

The second organic insulating layer 116 may be disposed on the connection electrode CM. The second organic insulating layer 116 may cover the connection electrode CM. The second organic insulating layer 116 and the first organic insulating layer 115 may include a same material or different materials.

A light-emitting diode may be disposed on the second organic insulating layer 116. In an embodiment, an organic light-emitting diode OLED may be disposed on the second organic insulating layer 116. In another embodiment, although not shown, an inorganic light-emitting diode may be disposed on the second organic insulating layer 116.

The organic light-emitting diode OLED may emit red, green, or blue light, or emit red, green, blue, or white light. The organic light-emitting diode OLED may include a first electrode 211, an emission layer 212b, a functional layer 212f, a second electrode 213, and a capping layer 215. The first electrode 211 may be a pixel electrode (e.g., an anode) of the organic light-emitting diode OLED, and the second electrode 213 may be an opposite electrode (e.g., a cathode) of the organic light-emitting diode OLED.

The first electrode 211 may be disposed on the second organic insulating layer 116. The first electrode 211 may be electrically connected to the connection electrode CM through a contact hole defined in the second organic insulating layer 116. The first electrode 211 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In an embodiment, the first electrode 211 may include a reflective layer including Ag, Mg, Al, Pt, Pd, Au, Ni, Nd, Ir, Cr, or a compound thereof. In an embodiment, the first electrode 211 may further include a layer including ITO, IZO, ZnO, or In₂O₃ above/below the reflective layer described above. For example, the first electrode 211 may have a multi-layer structure of ITO/Ag/ITO.

A pixel defining layer 118 including an opening exposing at least a portion of the first electrode 211 may be disposed on the first electrode 211. An emission region of light emitted from the organic light-emitting diode OLED may be defined by the opening of the pixel defining layer 118. For example, the width of the opening may correspond to the width of the emission area.

The pixel defining layer 118 may include an organic insulating material. In another embodiment, the pixel defining layer 118 may include an inorganic insulating material, such as silicon nitride, silicon oxynitride, and silicon oxide. In another embodiment, the pixel defining layer 118 may include an organic insulating material and an inorganic insulating material. In an embodiment, the pixel defining layer 118 may include a light blocking material. The light blocking material may include a resin or paste including carbon black, carbon nanotube, a black pigment, metal particles such as Ni, Al, Mo, an alloy thereof, metal oxide particles (e.g., chromium oxide), or metal nitride particles (e.g., chromium nitride). In case that the pixel defining layer 118 includes a light blocking material, external light reflections due to metal structures disposed under the pixel defining layer 118 may be reduced.

A spacer 119 may be disposed on the pixel defining layer 118. The spacer 119 may include an organic insulating material, such as polyimide. In another embodiment, the spacer 119 may include an inorganic insulating material such as SiNₓ or SiO₂ or may include an organic insulating material and an inorganic insulating material.

In an embodiment, the spacer 119 and the pixel defining layer 118 may include a same material and may be formed together by a mask process using a halftone mask. In another embodiment, the spacer 119 and the pixel defining layer 118 may include different materials.

The emission layer 212b may be arranged in the opening of the pixel defining layer 118. The emission layer 212b may include a high molecular-weight or low molecular-weight organic material emitting a color of light.

The functional layer 212f may include a first functional layer 212a and a second functional layer 212c. The first functional layer 212a may be arranged between the first electrode 211 and the emission layer 212b, and the second functional layer 212c may be arranged between the emission layer 212b and the second electrode 213. However, the disclosure is not limited thereto, and in another embodiment, at least one of the first functional layer 212a and the second functional layer 212c may be omitted. Hereinafter, an embodiment that the first functional layer 212a and the second functional layer 212c are each arranged will be described in detail.

The first functional layer 212a may include a hole transport layer (HTL) and/or a hole injection layer (HIL). The second functional layer 212c may include an electron transport layer (ETL) and/or an electron injection layer (EIL). The first functional layer 212a and/or the second functional layer 212c may be a common layer entirely covering the substrate 100 similarly to the second electrode 213 to be described below.

The second electrode 213 may be disposed on the functional layer 212f. The second electrode 213 may include a conductive material having a low work function. For example, the second electrode 213 may include a transparent (or transflective) layer including Ag, Mg, Al, Pt, Pd, Au, Ni, Nd, Ir, Cr, Li, Ca, or an alloy thereof. In another embodiment, the second electrode 213 may further include a layer including ITO, IZO, ZnO, or In₂O₃, on the transparent (or transflective) layer.

In an embodiment, the capping layer 215 may be disposed on the second electrode 213. The capping layer 215 may include LiF, an inorganic material, and/or an organic material.

An encapsulation layer 300 may be disposed on the organic light-emitting diode OLED. The encapsulation layer 300 may cover the organic light-emitting diode OLED. The encapsulation layer 300 may be disposed on the second electrode 213 and/or the capping layer 215. In an embodiment, the encapsulation layer 300 may include at least one inorganic encapsulation layer and at least one organic encapsulation layer. FIG. 10 illustrates an encapsulation layer 300 including a first inorganic encapsulation layer 310, an organic encapsulation layer 320, and a second inorganic encapsulation layer 330, which are sequentially stacked.

The first inorganic encapsulation layer 310 and the second inorganic encapsulation layer 330 may each include at least one of Al₂O₃, TiO₂, Ta₂O₅, HfO₂, ZrO₂, SiO₂, SiNₓ, and SiON. The first inorganic encapsulation layer 310 and the second inorganic encapsulation layer 330 may each be a single layer or a multi-layer including the material described above. The organic encapsulation layer 320 may include a polymer-based material. The polymer-based material may be an acryl-based resin, an epoxy-based resin, polyimide, polyethylene, etc. In an embodiment, the organic encapsulation layer 320 may include acrylate.

An input detection layer 400 may be disposed on the encapsulation layer 300. The input detection layer 400 may include a first touch insulating layer 410, a second touch insulating layer 420, a first conductive layer 430, a third touch insulating layer 440, a second conductive layer 450, and a planarization layer 460.

In an embodiment, the first touch insulating layer 410 may be disposed on the second inorganic encapsulation layer 330, and the second touch insulating layer 420 may be disposed on the first touch insulating layer 410. In an embodiment, the first touch insulating layer 410 and the second touch insulating layer 420 may each include an inorganic insulating material and/or an organic insulating material. For example, the first touch insulating layer 410 and the second touch insulating layer 420 may include an inorganic insulating material such as SiO₂, SiNₓ, and/or SiON.

In an embodiment, at least one of the first touch insulating layer 410 and the second touch insulating layer 420 may be omitted. For example, the first touch insulating layer 410 may be omitted, and the second touch insulating layer 420 may be disposed on the second inorganic encapsulation layer 330 and the first conductive layer 430 may be disposed on the second touch insulating layer 420.

The first conductive layer 430 may be disposed on the second touch insulating layer 420, and the third touch insulating layer 440 may be disposed on the first conductive layer 430. In an embodiment, the third touch insulating layer 440 may include an inorganic insulating material and/or an organic insulating material. For example, the third touch insulating layer 440 may include an inorganic insulating material such as SiO₂, SiNₓ, and/or SiON.

The second conductive layer 450 may be disposed on the third touch insulating layer 440. A touch electrode TE of the input detection layer 400 may have a structure that the first conductive layer 430 is connected with the second conductive layer 450. In another embodiment, the touch electrode TE may be formed in one of the first conductive layer 430 and the second conductive layer 450 and may include a metal line in the corresponding conductive layer. The first conductive layer 430 and the second conductive layer 450 may each include at least one of Al, Cu, Ti, MO, and ITO, and may be include layers or a single layer including the material described above. For example, the first conductive layer 430 and the second conductive layer 450 may each have a three-layer structure of Ti/Al/Ti.

In an embodiment, the planarization layer 460 may cover the second conductive layer 450. The planarization layer 460 may include an organic insulating material.

In an embodiment, the first release film 501 and the edge of the second release film 502 may have a step difference, and the thickness t1 of the first release film 501 may be in a range of about 10 μm to about 20 μm. In case that the thickness t1 of the first release film 501 is in a range of about 10 μm to about 20 μm, when forming the coating layer 800 by applying the coating layer forming material 800s (FIG. 6) on the heat dissipation layer 601, the thickness t2 of the coating layer 800 may be less than or equal to about 20 μm even in case that the coating layer forming material 800s is clumped at the side of the first release film 501 or is pushed over the first release film 501.

The thickness t2 of the coating layer 800 may be less than or equal to about 20 μm to allow pressure to be appropriately applied to attach the set on the display device 1 and for a connecting force between the set and the display device 1 to be maintained, thereby improving the quality and reliability of the display device 1.

According to an embodiment, a display device having improved reliability and quality and a method of manufacturing the display device may be implemented. However, the scope of the disclosure is not limited by these effects.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a display panel;
a cover panel disposed under the display panel and including a heat dissipation layer;
a first release film disposed under the cover panel and having a step difference with an edge of the cover panel; and
a second release film disposed under the first release film and having a step difference with an edge of the first release film.

2. The display device of claim 1, wherein a thickness of the first release film is in a range of about 10 μm to about 20 μm in a thickness direction of the display panel.

3. The display device of claim 1, wherein at least a portion of the cover panel is exposed due to the step difference with the edge of the first release film.

4. The display device of claim 1, wherein a step difference is formed between the first release film and an edge of the heat dissipation layer of the cover panel.

5. The display device of claim 1, wherein the heat dissipation layer comprises copper (Cu).

6. The display device of claim 1, wherein the cover panel further comprises a cushion layer disposed on the heat dissipation layer.

7. The display device of claim 1, wherein a step difference is formed between the cover panel and an edge of the display panel.

8. The display device of claim 1, further comprising:
a cover glass disposed on the display panel.

9. The display device of claim 8, wherein a step difference is formed between the cover glass and an edge of the display panel.

10. The display device of claim 9, wherein at least a portion of the cover glass is exposed due to the step difference with the edge of the display panel.

11. The display device of claim 1, further comprising:
a coating layer disposed on a portion of the heat dissipation layer of the cover panel exposed by the first release film.

12. The display device of claim 11, wherein the coating layer comprises at least one of propane (C₃H₈) and butane (C₄H₁₀).

13. The display device of claim 11, wherein the coating layer is arranged in at least a portion of a side of the first release film.

14. The display device of claim 11, wherein a thickness of the coating layer is less than or equal to about 20 μm in a thickness direction of the display panel.

15. The display device of claim 11, wherein the coating layer is arranged at a side of the cover panel and at least a portion of a lower surface of and a side of the display panel.

16. A method of manufacturing a display device, the method comprising:
arranging a cover panel including a heat dissipation layer on a display panel;
arranging a first release film on the cover panel such that a step difference with an edge of the cover panel is formed;
arranging a second release film on the first release film such that a step difference with an edge of the first release film is formed; and
forming a coating layer by applying a coating layer forming material on the heat dissipation layer of the cover panel about 0.1 mm apart from the edge of the first release film.

17. The display device of claim 16, wherein a thickness of the first release film is in a range of about 10 μm to about 20 μm in a thickness direction of the display panel.

18. The display device of claim 16, wherein the coating layer comprises at least one of propane (C₃H₈) and butane (C₄H₁₀).

19. The display device of claim 16, wherein the coating layer is disposed on a portion of the heat dissipation layer of the cover panel.

20. The display device of claim 19, further comprising:
forming a cover glass under the display panel.
